(19) United States
(12) Patent Application Publication
(10) Pub. No.: US 2024/0429199 A1
(43) Pub. Date: Dec. 26, 2024

(54) METHODS AND APPARATUS FOR SELF-ALIGNING BATCH PICK AND PLACE DIE BONDING

(71) Applicant: Intel Corporation, Santa Clara, CA (US)

(72) Inventors: Yi Shi, Chandler, AZ (US); Bhaskar Jyoti Krishnatreya, Hillsboro, OR (US); Feras Eid, Chandler, AZ (US); Xavier Brun, Hillsboro, OR (US); Johanna Swan, Scottsdale, AZ (US)

(21) Appl. No.: 18/340,635

(22) Filed: Jun. 23, 2023

(51) Int. Cl. H01L 23/00; H01L 21/67; H01L 21/68; H01L 21/683

(52) U.S. Cl. CPC H01L 24/97; H01L 21/67144; H01L 21/68; H01L 21/6838; H01L 24/83; H01L 2224/83896; H01L 2224/95146; H01L 2224/97

(57) ABSTRACT

Systems, apparatus, articles of manufacture, and methods are disclosed to self-align batch pick and place die bonding. Disclosed is an apparatus comprising a fluid dispensing assembly to dispense first amounts of water onto first hydrophilic regions of a first semiconductor wafer at a first point in time, the first hydrophilic regions having a first arrangement, and dispense second amounts of water onto second hydrophilic regions of a second semiconductor wafer at a second point in time, the second hydrophilic regions having a second arrangement, and a pick-and-place assembly to simultaneously position, at the first point in time, a first batch of dies corresponding to the first arrangement onto the first amounts of water dispensed on the first semiconductor wafer, and simultaneously position, at the second point in time, a second batch of dies corresponding to the second arrangement onto the second amounts of water dispensed on the second semiconductor wafer.

### FIELD OF THE DISCLOSURE

This disclosure relates generally to semiconductor die bonding and, more particularly, to methods and apparatus for self-aligning batch pick and place die bonding.

### BACKGROUND

Die-to-wafer bonding processes bond semiconductor dies directly to wafers. In die-to-wafer bonding processes, the semiconductor dies are fabricated on an initial wafer and then cut to size (e.g., singulated) prior to being placed on and bonded to the target wafer. In some instances, die-to-wafer bonding processes include fusion and/or hybrid bonding.

### BRIEF DESCRIPTION OF THE DRAWINGS

FIG. 1 shows an example die-to-wafer self-aligning and bonding process.

FIG. 2 shows an example die-to-wafer bonding process that involves the reconstitution of the source wafer of FIG. 1.

FIG. 3 shows example die arrangements for placement on a wafer.

FIG. 4 shows an example pick-and-place assembly for picking up the example die arrangements of FIG. 3.

FIG. 5 shows the example pick-and-place assembly of FIG. 4 picking up the dies of FIG. 3.

FIG. 6 shows an example wafer including the dies of FIG. 3.

FIG. 7 shows the example wafer of FIG. 6 before and after the application of water to facilitate the self-alignment of the example dies of FIG. 2 on the example wafer of FIG. 6.

FIG. 8 shows a first example nozzle head which can be used on the example pick-and-place assembly of FIG. 4.

FIG. 9 shows a second example nozzle head which can be used on the example pick-and-place assembly of FIG. 3.

FIG. 10 shows an example fluid dispensing assembly to dispense water on the example wafer of FIG. 6.

FIGS. 11-13 show a first example bonding machine for dispensing fluid and picking and placing the dies of FIG. 3.

FIGS. 14-16 show a second example bonding machine for dispensing fluid and picking and placing the dies of FIG. 3.

FIGS. 17-19 are flowcharts representative of example methods to implement the example die-to-wafer self-aligning and bonding process of FIGS. 1 and/or 2.

FIG. 20 is a block diagram of an example processing platform including programmable circuitry structured to execute, instantiate, and/or perform the example machine readable instructions and/or perform the example operations of FIGS. 17-19 to implement the example die-to-wafer self-aligning and bonding process 100 of FIG. 1.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

Traditional die-to-wafer bonding processes bond one die (e.g., semiconductor die) at a time (including flip chip bonding, thermal compression bonding (TCB), and direct hybrid bonding). In some industries, such as the micro-LED industry, die-to-wafer bonding processes can transfer multiple dies at a time, but the configuration of dies being collectively transferred is limited to multiple dies of the same type and size and arranged in a particular layout. Using such techniques, transferring and bonding different types, sizes, and/or layouts of dies would require a different process using different machinery configured for the particular dies to be transferred. Thus, transferring multiple dies based on known approaches is still a time consuming operation. As die sizes continue to get smaller, considerable time is spent placing dies one by one on a target wafer, where the target wafer may include thousands to tens of thousands of dies.

In the context of die-to-wafer bonding, hybrid bonding involves the permanent bonding of both (i) interfacing dielectric (e.g., SiOx) surfaces on the die and wafer and (ii) interfacing metal (e.g., Cu) surfaces on the die and wafer. The interfacing metal surfaces provide electrical interconnections between the die and the wafer. Hybrid bonding enables heterogeneous integration for directly connecting dies of different functions, sizes, orientations, etc.

However, no known bonding process is capable of bonding multiple dies of different types with different sizes and layouts at the same time while also allowing fine adjustments of bond placement at the die level. Collective die-to-wafer bonding allows the ability to bond multiple dies of different sizes and orientations but requires precise die placement on the wafer since the dies do not self-align. Therefore, the machinery and configurations in which dies are placed on the wafer need to be changed to accommodate different types, sizes, orientations, and/or layouts of dies for such precise die placement. This is problematic, notably, for hybrid bonding techniques where the bonding process needs to occur quickly (e.g., the fluid may evaporate) or where a wash and clean process needs to occur before the fluid is placed.

In hybrid bonding, dies are attached to the target wafer via van der Waals forces at room temperature. A thermal annealing process is applied to the entire wafer post bonding to allow covalent bonds formed between interfacing dielectric surfaces and direct copper-to-copper bonds formed between interfacing copper surfaces by diffusion.

As disclosed herein, to enable self-assembly mechanism during bonding, fluid (typically deionized (DI) water) is dispensed at bonding sites. Capillary forces in the fluid enable the dies to self-align into desired positions. In some examples, the fluid placed is very small in volume (e.g., less than 1 microliter per die) and is evaporated quickly without intervention. Therefore, the action of dispensing the fluid and placing the dies must occur quickly to prevent the fluid from evaporating before the dies are placed.

When machinery needs to change to accommodate different sized dies (and/or a different arrangement of dies), the process of placing the dies and bonding said dies to the target wafer increases production time. In some examples, the arrangement of dies to be placed on the target wafer changes with each placement of the dies, and the amount of fluid dispensed to bond those dies to the target wafer is only enough to accommodate the current arrangement of dies to be placed. With every change in machinery, there is likely a corresponding increase in production time to allow for the changing of the machinery and the halting of dispensing fluid.

Additionally, the accuracy of the machinery and configurations necessary to place the semiconductor dies to a tolerable accuracy (for example, 200 nanometers (nm) or less) is problematic. Slight variations in semiconductor die alignment on the wafer can produce non-usable components. To counter these potential misalignments, machinery may need to move slower to be more precise in picking up and placing the dies on the target wafer. Additionally, powerful vision systems are needed for the machinery to precisely align the die to target wafer during the bonding process. Also, changes to the configuration/machinery can result in the need to re-calibrate the machinery, which is costly in manufacturing time. As the tolerances decrease (for example, in tolerances less than 1 micrometer (μm)), the need for increased precision in placing the dies is imperative for creating an operable component.

By contrast, the self-aligning configuration disclosed herein does not require precise positioning of the dies due to the dies being able to self-align after placement on the target wafer in a relatively close position (e.g., within a defined tolerance). Increasing precision tolerances (e.g., allowing for greater variability) in placing dies on the target wafer subsequently result in decreases in manufacturing/production time.

Examples disclosed herein provide a configuration that can pick and place semiconductor dies of different types, sizes, orientations, and/or layouts on a wafer without the need to modify the configuration for those different arrangement of semiconductor dies. Examples disclosed herein also provide a self-aligning configuration to reduce the need for the precise placement of the semiconductor dies on the wafer.

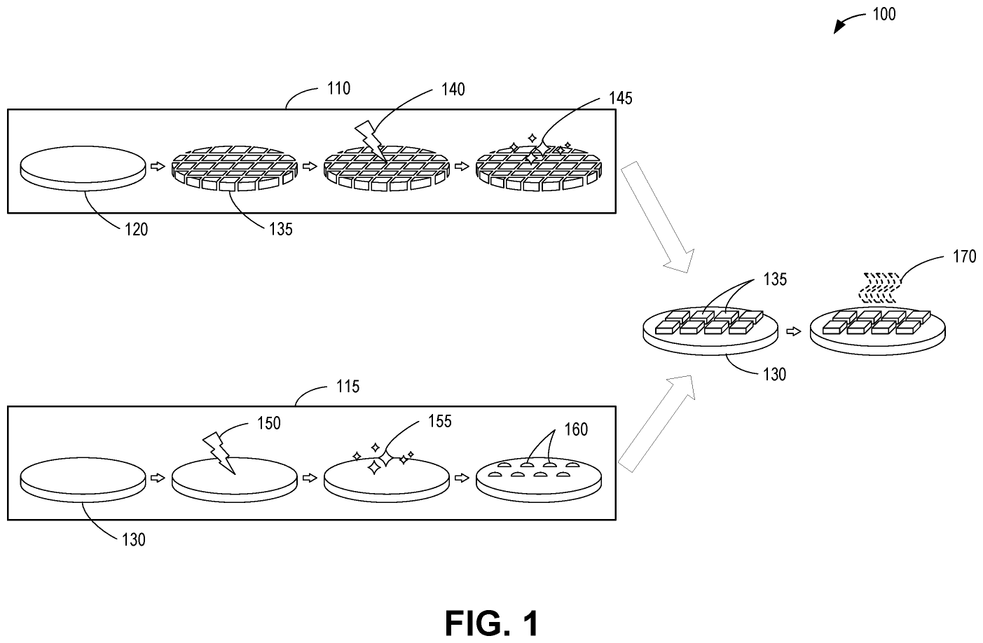

FIG. 1 shows an example die-to-wafer self-aligning and bonding process 100. The die-to-wafer self-aligning and bonding process 100 includes a first wafer 120 and a second wafer 130. In this example, the dies (e.g., semiconductor dies 135) are initially on the first wafer 120 (also referred to herein as a source wafer) and transferred and bonded to the second wafer 130 (also referred to herein as a target wafer). In the illustrated example of FIG. 1, the source wafer 120 is a semiconductor wafer on which individual semiconductor dies are fabricated using any suitable fabrication processes.

In the example disclosed herein, the first (source) wafer 120 goes through a first preparation process 110 and the second (target) wafer 130 goes through a second preparation process 115. The first and second preparation processes 110, 115 can be performed independent of one another. Thus, in some examples, the first and second preparation processes 110, 115 are implemented in parallel. The first preparation process 110 begins with the top surface of the first wafer 120 being smoothed, flattened, or polished by a chemical mechanical planarization (CMP) process. Having a smooth and/or flat surface facilitates the hybrid bonding to occur later in the process. Once planarized, the first wafer 120 is cut (e.g., singulated, diced) to obtain semiconductor dies 135. In some examples, the semiconductor dies 135 are cut into pre-defined shapes and orientations which are determined based on the application in which the semiconductor dies 135 are to be used (e.g., a processor, memory, an integrated circuit, etc.).

The semiconductor dies 135 of the first wafer 120 are subjected to a first plasma activation 140. In some examples, the first plasma activation 140 applies a plasma treatment (e.g., using an ionized gas, such as N₂, H₂, and O₂, to form plasma) to the semiconductor dies 135 to change the surface chemistry of bonding points (e.g., activates or energizes the surface to increase adhesion characteristics) of the semiconductor dies 135 to increase a bonding strength between the semiconductor dies 135 and the second wafer 130.

After the semiconductor dies 135 are subjected to the first plasma activation 140, the semiconductor dies 135 are subjected to a first cleaning/hydration 145. The first cleaning 145 removes any unwanted debris from the surface of the bonding points (e.g., produced from the dicing process or otherwise) and ensures that the bonding points are properly prepared for bonding. The first cleaning 145 also serves as a hydration step to increase an amount of hydroxyl (OH) groups on the surface.

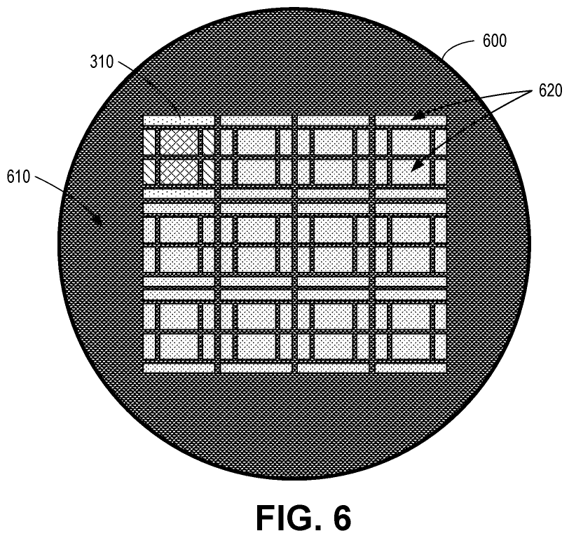

The second preparation process 115 for the second (target) wafer 130 has similarities with the first preparation process 110. For instance, the second preparation process 115 begins with the top surface of the second wafer 130 undergoing a CMP process to smooth, flatten, or polish the surface. Once planarized, the second wafer 130 is subjected to a second plasma activation 150 (e.g., similar process to that of the first plasma activation 140). In some examples, the target wafer 130 is formed to include multiple materials (e.g., silicon, germanium, etc.) to create contrasting regions on the surface of the target wafer 130. In some such examples, the target wafer 130 has contrasting regions corresponding to hydrophilic regions that attract fluids and hydrophobic regions that repel fluids. The hydrophobic and hydrophilic regions are discussed further herein with respect to FIG. 6.

In examples disclosed herein, the second plasma activation 150 activates the surface of the second wafer 130 to promote increased bonding/adhesion properties. The second plasma activation 150 ensures that the semiconductor dies 135, when placed on the second wafer 130, bond to the second wafer 130 using the die-to-wafer hybrid bonding process disclosed herein.

The second wafer 130 is subjected to a second cleaning 155. The second cleaning 155 removes any unwanted debris from the surface of the second wafer 130 and ensures that the bonding points are properly prepared for bonding, similar to that of the first cleaning 145.

To perform the die-to-wafer self-aligning and bonding process 100 disclosed herein, water droplets 160 are placed on the second wafer 130, defining where the semiconductor dies 135 are to bond to the second wafer 130. In examples disclosed herein, the water droplets 160 are placed on the hydrophilic regions of the second wafer 130. Due to the hydrophilic properties of the region, the water droplets 160 will spread out in a thin film rather than bead up on the surface. However, due to the hydrophobic regions surrounding the hydrophilic regions, the water will spread up to but not over the edge of the hydrophilic regions such that the water droplets 160 remain in the desired locations (e.g., within the hydrophilic regions) on the second wafer 130. This allows the semiconductor dies 135, once placed on the water droplets 160, to self-align through capillary forces that force the semiconductor dies 135 into alignment with the hydrophilic regions. In some examples, the amount or volume of the water droplets 160 dispensed on a given hydrophilic region is controlled to be sufficient to cover the entire hydrophobic regions with a relatively thin film layer of water having a relatively controlled volume (e.g., less than 1 microliter (μm) and can be on the nanoliter scale). Thus, larger hydrophilic regions will have more water than smaller hydrophilic regions.

After the water droplets 160 have been placed on the second wafer 130, the first and second preparation processes 110, 115 are complete and the semiconductor dies 135 are then picked up and placed on the second wafer 130 at the hydrophilic regions. While the separate preparation processes 110, 115 can be done in parallel and/or at different times, the dispensing of the water droplets 160 is done close in time to when the semiconductor dies 135 are to be transferred from the first (source) wafer 130 to the second (target) wafer 130 so that water is still present when the dies 135 are placed thereon. This timeframe is relatively small because the volume of the water droplets is relatively small and, therefore, may evaporate relatively quickly. In this example, the alignment of the semiconductor dies 135 does not need to be as precise as many known pick and place processes (e.g., sub-micron precision for existing processes while the process disclosed herein can operate properly with a precision at the tens of microns level) because the thin film layer of water that is already precisely spread across the hydrophilic region will cause a slightly misaligned die 135 to move into alignment with the underlying hydrophilic region (based on water surface tension properties and/or capillary action of the water interacting with the interfacing surface of the die 135 which is also prepared with a hydrophilic surface). Inasmuch as the self-aligning capabilities of the water enables the initial alignment of the dies from the pick and place process to be less precise than known approaches, the pick and place process disclosed herein can be done at a faster speed than known approaches.

The combined semiconductor dies 135 and second wafer 130 are then subjected to a thermal annealing process 170 to form covalent bonds at a dielectric-to-dielectric bonding interface of the dies 135 to bond the dies 135 to the second wafer 130. In some examples, the thermal annealing process 170 includes subjecting the combined semiconductor dies 135 and second wafer 130 to a temperature between 200° C.-450° C. The resulting component includes the semiconductor dies 135 fully bonded to the second wafer 130.

As discussed above, in the illustrated example of FIG. 1, it is assumed that the first (source) wafer 130 is an original semiconductor wafer on which the semiconductor dies 135 were fabricated. However, in other examples, the source wafer 130 may be a reconstituted wafer that includes semiconductor dies fabricated on one or more other wafers and then transferred to the reconstituted wafer.

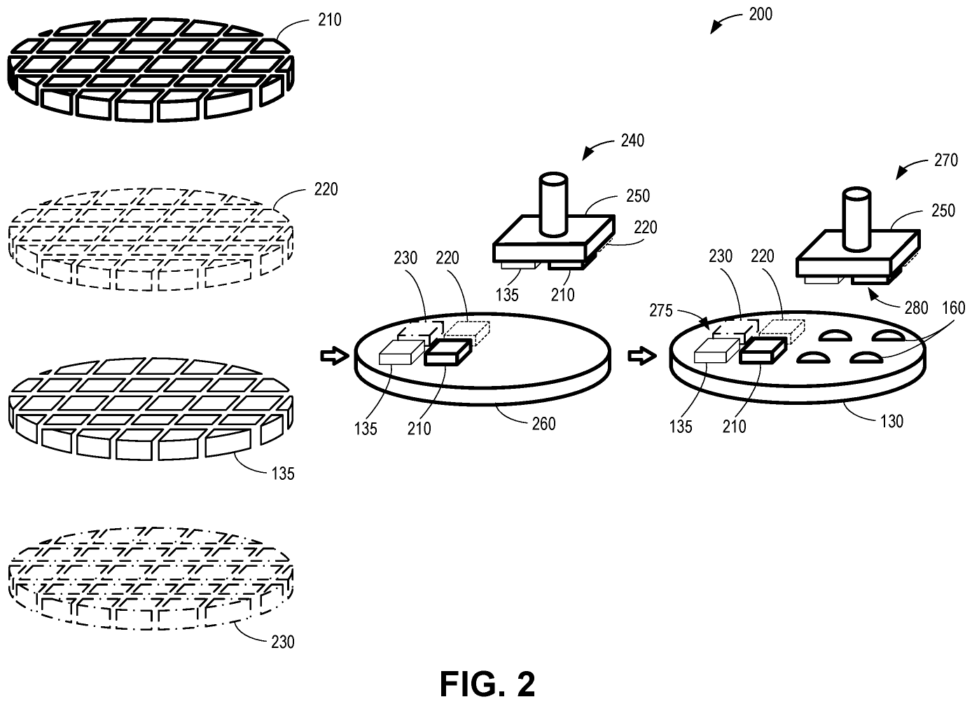

FIG. 2 shows an example die-to-wafer bonding process flow 200 that involves reconstitution of semiconductor dies to be bonded from their respective source wafers to an intermediate reconstituted wafer. The example process flow 200 enables picking, placing, and subsequent capillary force driven self-alignment of multiple dies of different types, sizes, fabrication nodes, etc. simultaneously in batches containing multiple dies. In the illustrated example, the second wafer 130 (e.g., a semiconductor wafer) includes dies (e.g., semiconductor dies 135) cut from different wafers (e.g., more than one first wafer 120). One such example, as illustrated in FIG. 2, shows the semiconductor dies 135 (e.g., first dies), second dies 210, third dies 220, and fourth dies 230 associated with four separate wafers.

At a first die placement stage 240 (e.g., a wafer reconstitution stage, a first pick-and-place operation) of FIG. 2, a pick-and-place assembly 250 collects/picks up the first dies 135, second dies 210, third dies 220, and fourth dies 230 and moves them to a carrier 260. The carrier 260 may correspond to a semiconductor wafer and/or any other suitable material that can serve as the underlying substrate for a reconstituted wafer. The carrier 260 supports the dies 135, 210, 220, 230 in a desired spatial relationship or layout for subsequent transfer to the second (final target) wafer 130. Thus, the carrier 260 initially functions as a “target wafer” to which the dies 135, 210, 220, 230 are transferred from corresponding “source wafers” (shown at left in FIG. 2), and then the carrier 260 (as a reconstituted wafer) becomes the “source wafer” for a second pick-and-place stage 270 (e.g., a second pick-and-place operation). In examples disclosed herein, the dies placed on the second wafer 130 can include any combination of dies and need not contain only dies from a single wafer (e.g., the semiconductor dies 135). As such, the example reconstitution process associated with the first die placement stage 240 of FIG. 2 is to enable the arrangement of multiple different dies from different wafers in a desired layout for subsequent bulk (batch) transfer to a final target wafer (e.g., the second wafer 130).

Transferring the dies 135, 210, 220, 230 to the carrier 260 to generate a reconstituted wafer may appear to increase production time by introducing intermediate operations of moving the dies 135, 210, 220, 230 from their original source wafers. However, this process can be performed relatively quickly because the alignment of the dies 135, 210, 220, 230 being reconstituted on the carrier 260 does not need to be very precise based on the fact that the dies 135, 210, 220, 230 will be moved again and to the final target wafer 130 and temporary misalignments will be resolved through the die-to-wafer self-aligning and bonding process 100 disclosed herein. Furthermore, by reconstituting the dies 135, 210, 220, 230 on to the carrier wafer 260, the process of moving the dies 135, 210, 220, 230 to the final target wafer 130 can be performed much more quickly because the pick-and-place assembly 250 can pick up and move multiple dies (e.g., a batch of dies) simultaneous that are already in proper arrangement relative to one another (based on the reconstitution of the dies 135, 210, 220, 230 on the carrier 260). At the first die placement stage 240, the water droplets 160 are not necessarily needed since the carrier 260 represents a temporary stage of the manufacturing process.

In some examples, once the reconstituted wafer (e.g., the carrier 260 filled with dies 135, 210, 220, 230) is created, the reconstituted wafer is taken through the first cleaning 145 as disclosed in connection with FIG. 1. In some examples, subjecting the reconstituted wafer to the first cleaning 145 has the advantage of cleaning the entire reconstituted wafer to ensure a clean and consistently smooth surface for improved hybrid bonding to the second wafer 130 after the second preparation stage 115.

At a second die placement stage 270, the pick-and-place assembly 250 positions the picks up the dies 135, 210, 220, 230 to place on the second wafer 130. In some examples, as represented in FIG. 2, this pick-and-place operation involves picking up multiple different ones of the dies 135, 210, 220, 230 at a single point in time (e.g., simultaneously) to then be transferred as a group, set, or batch on the second wafer 130. In some examples, the placement and subsequent bonding of the dies 135, 210, 220, 230 to the second wafer 130 follows the process set forth above in connection with FIG. 1. Thus, as illustrated in FIG. 2, a first batch 275 of the dies 135, 210, 220, 230 have already been transferred to the second wafer 130 and self-aligned through the capillary forces acting on the dies 135, 210, 220, 230.

Further, the pick-and-place assembly 250 is already holding a second batch 280 of the dies 135, 210, 220, 230 to be placed on the water droplets 160 that have already been dispensed onto the second wafer 130 for the second batch 280 of dies 135, 210, 220, 230. It should be understood the arrangement in which the dies 135, 210, 220, 230 are picked and placed by the pick-and-place assembly 250 is application-dependent. That is, the number, type, size, shape, and/or layout of the batch of dies picked up at a single time can differ for different applications. Thus, picking and placing such batches of dies of different dimensions reduces the time taken to transfer the dies to the second wafer 130 in combination with the reduction in precision placement of the dies because of the self-alignment of the dies. As the effect of plasma activation reduces over time, the time saved by picking and placing batches of dies can be beneficial, especially with very smaller die size (<3×3 mm) which would require huge amounts of time picking and placing one by one in some applications.

Examples disclosed herein are capable of picking and placing any suitable arrangement of dies (or any suitable number, type, size, shape, and/or layout) without a redesign or reconfiguration of the pick-and-place assembly 250. Thus, examples disclosed herein provide a universal semiconductor die pick and placement process irrespective of the arrangement of dies involved.

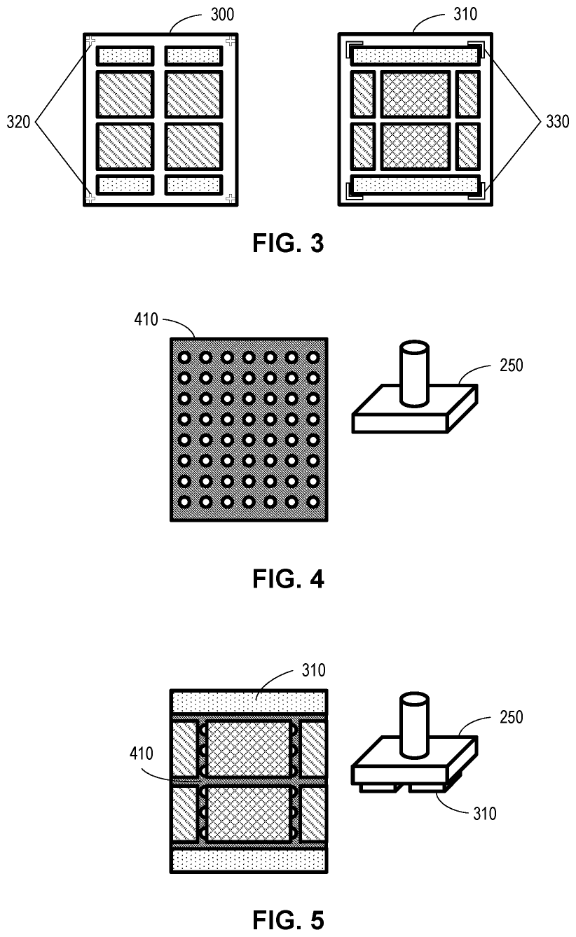

FIG. 3 shows example die arrangements for placement on a wafer (e.g., the second wafer 130). The example illustration of FIG. 3 shows a first die arrangement 300 and a second die arrangement 310. The first die arrangement 300 includes dies of differing shapes and sizes. The second die arrangement 310 includes a different set of dies of differing shapes and sizes compared to each other and relative to the first die arrangement 300. The example of FIG. 3 is purely to show that different die sizes, orientations, and/or configurations may be used to place on the second wafer 130. As such, while examples herein refer to using the first and second die arrangements 300, 310, any other arrangement may be used herein in which the dies are of different amounts, types, sizes, shapes, orientations, and/or layouts.

In some examples, the die arrangements 300, 310 correspond to a unit cell that is repeated across the wafer. The dies included in this unit cell may all be processed at a single point in time. Also shown in FIG. 3 are unit cell level fiducials 320 and die array corner fiducials 330. In some examples, the unit cell level fiducials 320 are provided on the bottom (target) wafer 130 to define markers that guide the alignment of the die arrangements 300, 310 when being transferred from a source wafer (e.g., a reconstituted wafer). In other examples, die array corner fiducials 330 are provided on the die arrangements 300, 310 themselves to assist in alignment and placement of the die arrangements 300, 310 on the bottom wafer 130. The fiducials 320, 330 define a boundary of the die arrangements 300, 310. Different die arrangements may thus change the fiducials 320, 330 to define those boundaries.

FIG. 4 is an example pick-and-place assembly 250 for picking up the example die arrangements 300, 310 of FIG. 3. In some examples, the pick-and-place assembly 250 includes a vacuum head 410 for picking up the dies 135, 210, 220, 230. In some examples, the nozzle head has a plurality of holes and pick-and-place assembly 250 uses a vacuum force to suction the dies 135, 210, 220, 230 to the vacuum head 410 for picking and placing on the second wafer 130. The pick-and-place assembly 250 is described in further detail herein. In some examples, the pick-and-place assembly 250 implements means for positioning a plurality of dies on the water droplets on a semiconductor wafer.

FIG. 5 is an illustration of the example pick-and-place assembly 250 of FIG. 4 picking the die arrangement 310 of FIG. 3. While the example illustration of FIG. 5 shows the pick-and-place assembly 250 picking up only one of the die arrangements described in FIG. 3, it should be understood that any die arrangement can be interchangeably used herein to be picked up by the pick-and-place assembly 250. The die arrangement 310 is suctioned to the vacuum head 410 via the vacuum force applied by the pick-and-place assembly 250 so that the die arrangement 310 can be picked up and placed on the second wafer 130. The vacuum head 410 corresponds in size (e.g., covers the boundary) defined by the fiducials 320, 330 of FIG. 3. Thus, the vacuum head 410 may be sized so as to pick up the die arrangements defined by the fiducials 320, 330.

FIG. 6 is an example wafer 600 including the die arrangements 300, 310 of FIG. 3. In examples disclosed herein, the wafer 600 (also referred to as the second wafer 130 of FIG. 1) includes a plurality of dies bonded to the surface of the wafer 600. As mentioned above, dies can be of different sizes, orientations, shapes, etc., and the pick-and-place assembly 250 can pick up and place multiple arrangements of dies.

The number of individual dies that can be placed on the wafer 600 is dependent on a size of the wafer 600. As illustrated in FIG. 6, the wafer 600 includes one instance of the second die arrangement 310 of FIG. 3 having been placed on the wafer 600. The wafer 600 includes hydrophobic regions 610 and hydrophilic regions 620, the hydrophilic regions 620 representing where additional dies are to be placed. As described above, in some examples, the pick-and-place assembly 250 transfers all of the dies in the second die arrangement 310 simultaneously. In some such examples, the pick-and-place assembly 250 repeats the process to transfer additional instances of the second die arrangement 310 to the wafer 600 onto corresponding unit cells of the hydrophilic regions 620. In some examples, the hydrophobic regions 610 and the hydrophilic regions 620 are created prior to the first and second preparation processes 110, 115. In such examples, the hydrophobic regions 610 and the hydrophilic regions 620 are thus created/defined prior to the cutting, picking, and placement of the dies 135, 210, 220, 230 on the second wafer 130. The hydrophobic regions 610 repel water/fluid and the hydrophilic regions 620 attract water/fluid.

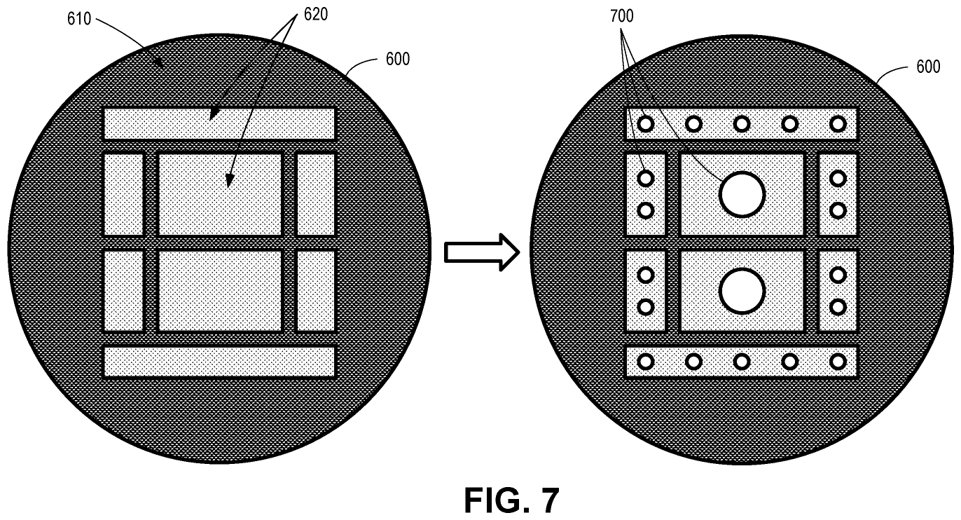

FIG. 7 shows the example wafer 600 of FIG. 6 before and after the application of water to facilitate the self-alignment of the example dies 135, 210, 220, 230 of FIG. 2 on the example wafer 600. As shown in FIG. 7, water droplets 700 are placed on the hydrophilic regions 620. In some examples, the hydrophilic regions 620 are different sizes, corresponding to different sized dies to be bonded to the wafer 600. In some examples, the size of each water droplet 700 and the amount of water droplets on each hydrophilic region 620 is tailored to the size of the die so that the water will cover the entire area of the hydrophilic regions 620 once the dies 135, 210, 220, 230 are placed on top. In some such examples, larger dies, with a corresponding larger hydrophilic region, are placed on a larger water droplet 700. In other such examples, dies of unique shapes (e.g., rectangular (including 90 degree edges, chamfered edges, hollowed middle (e.g., picture-frame shaped)) or any other shape known or interchangeable therein) are placed on multiple smaller water droplets.

As mentioned above, once the dies 135, 210, 220, 230 are placed on the water droplets 700, the water spreads out over the entire hydrophilic region 620, creating a boundary to align the entire dies 135, 210, 220, 230 to the wafer 600. Due to the inclusion of the hydrophobic regions 610 surrounding the hydrophilic regions 620, the water will spread up to the edge of the hydrophilic regions 620 without extending beyond this edge into the hydrophobic regions 610. This allows for less accuracy required in dispensing the water droplets 700 but still maintains precision control for which to self-align the dies 135, 210, 220, 230. This precise control with which the water spreads out enables the self-alignment of the dies 135, 210, 220, 230 by causing (through capillary forces) the dies 135, 210, 220, 230 to shift into alignment with the edge of the spread out water. By causing the dies 135, 210, 220, 230 to align with the edge of the spread out water (which is controlled by the edge of the hydrophilic regions 620), the dies 135, 210, 220, 230 will become aligned with the hydrophilic regions 620. Therefore, less accuracy is required to place the dies 135, 210, 220, 230 on the wafer 600 since the dies 135, 210, 220, 230 self-align using the water, the hydrophobic regions 610, and the hydrophilic regions 620. In some examples, the alignment accuracy achieved by this self-aligning process can be less than 200 nm.

In some examples, the water droplets 700 are dispensed on the hydrophilic regions 620 of FIG. 6 associated with different unit cells at different points in time. In some examples, at a first point in time, first amounts of the water droplets 700 are dispensed on first hydrophilic regions corresponding to a first area of the hydrophilic regions 620 (e.g., a first unit cell) defined by the fiducials 320, 330. In some examples, at a second point in time different than the first point in time, second amounts of the water droplets 700 are dispensed on second hydrophilic regions corresponding to a second area of the hydrophilic regions 620 (e.g., a second unit cell). In some examples, a first batch of dies (e.g., a first arrangement of the dies 135, 210, 220, 230) are simultaneously positioned on the first amounts of water. In some examples, a second batch of dies (e.g., a second arrangement of the dies 135, 210, 220, 230) are simultaneously positioned on the second amounts of water.

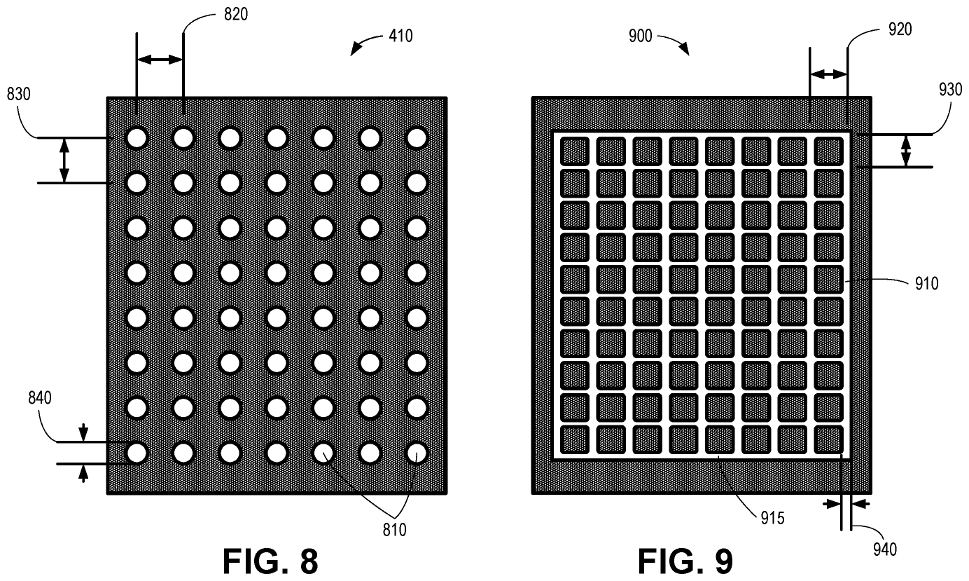

FIG. 8 is a first example vacuum head 410 which can be used on the example pick-and-place assembly 250 of FIG. 2 to pick and place the dies 135, 210, 220, 230 on the wafer 600. In the example of FIG. 8, the first vacuum head 800 includes openings 810 are circular and distributed across the first vacuum head 800 in a two-dimensional array. In other examples, the openings 810 can have any other suitable shape (e.g., square, oval, rectangular, triangular, oblong, elongate, etc.). The pick-and-place assembly 250 provides a vacuum force through the first vacuum head 800 to suction dies 135, 210, 220, 230 to the first vacuum head 800 to pick and place the dies 135, 210, 220, 230 onto the wafer 600.

In the example of FIG. 8, the openings 810 are spaced apart a first dimension 820 in a first direction, a second dimension 830 in a second direction, and the openings have a diameter 840. As shown in the example of FIG. 8, the first direction is horizontal across the first vacuum head 800 and the second direction is vertical across the first vacuum head 800 such that the array of openings 810 follow a rectangular or square pattern. In other examples, different arrangements are possible. For instance, the openings 810 may be arranged at angles to define a triangular pattern or a honeycomb (hexagonal) pattern. Regardless of the particular size, number, and/or spacing of the openings 810, in some examples, the openings 810 are arranged to be sufficiently small and sufficiently close together to pick up any suitable arrangement of dies including dies of any suitable size. Therefore, the openings 810 are arranged to align with any arrangement of the dies 135, 210, 220, 230 and are thus universal with respect to the size and/or orientation of dies to be picked up. Thus, as mentioned above, the first vacuum head 410 is capable of picking up all of the dies in both the first arrangement of dies 300 and the second arrangement of dies 310 shown in FIG. 3. In the example of FIG. 8, the first dimension 820 is approximately 500 micrometers (μm), the second dimension 830 is approximately 500 μm, and the diameter 840 is approximately 200 μm. However, the first dimension 820, second dimension 830, and diameter 840 can be increased or decreased in other examples. The openings 810 of the vacuum head 410 cover an area defined by the fiducials 320, 330 of FIG. 3 to be able to pick up all dies 135, 210, 220, 230 associated with a single fiducial 320, 330.

FIG. 9 is a second example vacuum head 900 which can be used on the example pick-and-place assembly 250 of FIG. 2. The second vacuum head 900 includes first elongate apertures 910 extending in a first direction and second elongate apertures 915 extending in a second direction to intersect with the first elongate apertures 910 and define an interconnected matrix as an opening to which a vacuum force is applied. In the example of FIG. 9, the second elongate apertures 915 traverse the first elongate apertures 910 at about a right angle (e.g., 90 degrees). However, the orientation in which the first and second elongate apertures 910, 915 traverse each can differ in other examples. In some examples, either the first or second elongate apertures 910, 915 are omitted such that the vacuum hear 900 is defined by an array of discrete elongate slots or openings that extend substantially the full length (or width) of the vacuum head.

As shown in FIG. 9, the first elongate apertures 910 are spaced apart in a first dimension 920, the second elongate apertures 915 are spaced apart in a second dimension 930, and the first and second elongate apertures 910, 915 have a width 940. In the example of FIG. 9, the first dimension 920 is approximately 300 μm, the second dimension 930 is approximately 300 μm, and the width 940 is approximately 100 μm. However, the first dimension 920, second dimension 930, and width 940 can be increased or decreased in other examples. In some examples, elongate apertures (as shown in FIG. 9) can be used in combination with localized openings (as shown in FIG. 8).

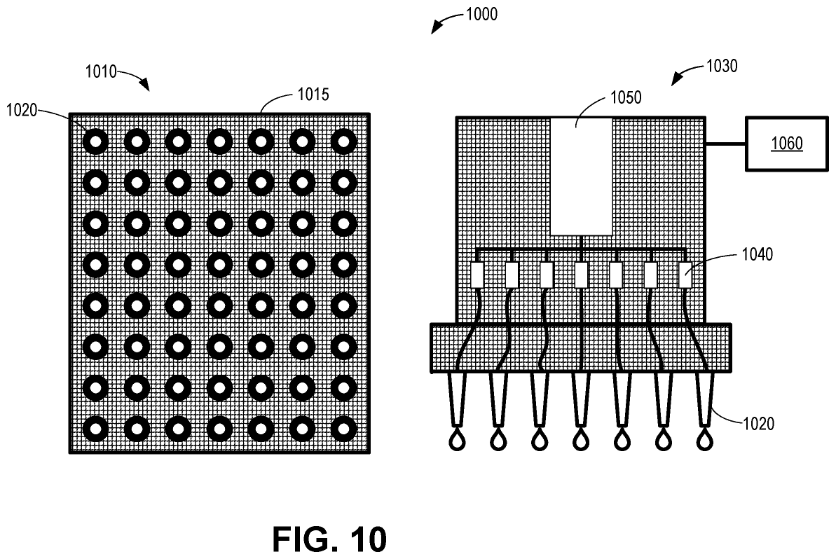

FIG. 10 is an example fluid dispensing assembly 1000 to dispense water on the example wafer 600 of FIG. 6. That is, the example fluid dispensing assembly 1000 enables and/or controls the dispensing of the water droplets 700 discussed above in connection with FIG. 7. A bottom view 1010 shows a nozzle head 1015 of the fluid dispensing assembly 1000. In this example, the nozzle head 1015 includes a two-dimensional array of nozzles 1020 spaced across the nozzle head 1015 for dispensing water/fluid onto the wafer 600. In some examples, the spacing of the nozzles 1020 is uniform (e.g., spaced evenly). In other examples, the spacing of the nozzles 1020 is non-uniform. Regardless of the particular size, number, and/or spacing of the nozzles 1020, in some examples, the nozzles 1020 are arranged to be sufficiently small and sufficiently close together to enable the application of water/fluid droplets to any suitable arrangement of hydrophilic regions within a single unit cell.

A side/cross-sectional view 1030 shows the nozzles 1020 for dispensing water/fluid onto the wafer 600, a plurality of valves 1040, a fluid source 1050, and fluid dispenser controller circuitry 1060.

The plurality of valves 1040 dispense water/fluid from the fluid source 1050 onto the wafer 600. In some examples, each valve 1040 can be controlled independently and is operably connected to the nozzles 1020. In some examples, the fluid source 1050 contains a static supply (e.g., a reservoir holding a pre-defined amount of fluid). In other examples, the fluid source 1050 contains a continuous supply of fluid (e.g., the fluid source 150 has a continuous supply of fluid). In some examples, the fluid source 1050 is a water source. In the illustrated example, the fluid source 1050 is shown as being part of the fluid dispensing assembly 1000. However, in other examples, the fluid source 1050 is separate from but fluidly coupled to the fluid dispensing assembly 1000. In some examples, the valves 1040 allow the water/fluid to flow through the valves 1040 and into the nozzles 1020 where the water/fluid is then dispensed onto the wafer 600. In some examples, the fluid dispensing assembly 1000 implements means for dispensing water on a semiconductor wafer.

The fluid dispenser controller circuitry 1060 controls the valves 1040. In some examples, the fluid dispenser controller circuitry 1060 independently controls the valves 1040 to regulate the amount of water/fluid dispensed through the nozzles 1020. In some examples, the valves 1040 are on/off valves that either block or permit fluid to be dispensed through the nozzles 1020 such that the amount of water/fluid through a given valve 1040 is controlled by how long the valve 1040 is opened. In other examples, the valves 1040 can control the flow rate of fluid through ones of the nozzles 1020 such that the amount of water/fluid is based on both how long the valve 1040 is opened and the flow rate permitted by the open valve. In some examples, where one individual nozzle 1020 may be positioned over larger hydrophilic regions 620 (e.g., corresponding to a larger die size), a larger volume of water can be dispensed through the nozzle 1020. Likewise, with smaller hydrophilic regions 620, a smaller volume of water can be dispensed through the nozzle 1020 through the independent control of the valves 1040. In other examples, a substantially consistent amount of water is dispensed through different ones of the nozzles 1020. In such examples, different amounts of water are applied to different sizes of hydrophilic regions 620 due to the number of nozzles 1020 aligned with each hydrophilic region 620. Additionally or alternatively, in some examples, at least some of the valves 1040 align with smaller hydrophilic regions 620 will remain closed to reduce the amount of water dispensed to those regions relative to larger hydrophilic regions 620. In some examples, the fluid dispenser controller circuitry 1060 implements means for regulating an amount of water/fluid to be dispensed through each nozzle 1020 of the fluid dispensing assembly 1000.

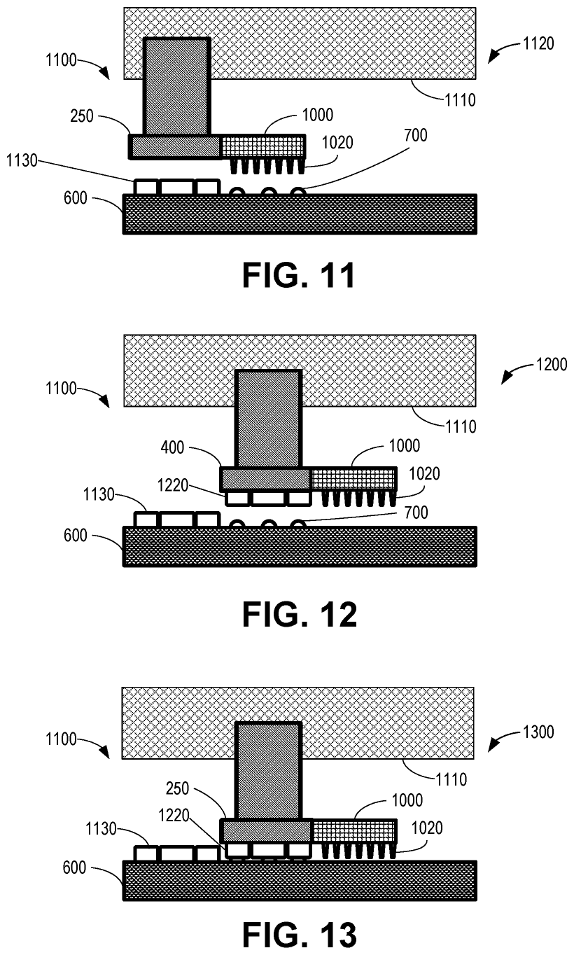

FIGS. 11-13 illustrate a first example bonding machine 1100 for dispensing fluid and picking and placing the dies of FIG. 3. The first example bonding machine 1100 includes the example fluid dispensing assembly 1000 of FIG. 10 and the example pick-and-place assembly 250 of FIG. 2. In this example, the fluid dispensing assembly 1000 and the pick-and-place assembly 250 fixedly coupled/joined together to operate and/or move as a unit. In some examples, the collective movement of both the fluid dispensing assembly 1000 and the pick-and-place assembly 250 is implemented by a first gantry 1110. In some examples, the first gantry 1110 includes robotic arms, hydraulic actuators, etc., to move the first example bonding machine 1100 to place the dies 135, 210, 220, 230 and dispense the water (e.g., the water droplets 700 of FIG. 7). In the illustrated example of FIGS. 11-13, the fluid dispensing assembly 1000 and the pick-and-place assembly 250 move as one and can perform their respective actions (e.g., dispense fluid and pick up/position dies respectively) in parallel (e.g., simultaneously). That is, while the pick-and-place assembly 250 is placing a first batch of dies onto the semiconductor wafer 600, the fluid dispensing assembly 1000 dispenses water droplets on an adjacent area to prepare that area to receive a second batch of dies.

FIG. 11 shows the first example bonding machine 1100 in a first position 1120. The first position 1120 shows the pick-and-place assembly 250 just after having placed a first batch of dies 1130 (e.g., the dies 135, 210, 220, 230) and the fluid dispensing assembly 1000 just after having dispensed the water droplets 700 on the wafer 600 adjacent the first batch of dies 1130 in preparation for a second batch of dies. As disclosed herein, the pick-and-place assembly 250 can pick up any arrangement of dies, and thus the dies 135, 210, 220, 230 can be in any order or arrangement when picked up by the pick-and-place assembly 250. Similarly, in this example, the fluid dispensing assembly 1000 can dispense water droplets onto any arrangement of hydrophilic regions on the semiconductor wafer 600 corresponding to the arrangement of dies carried by the pick-and-place assembly 250. Thus, in this example, the vacuum head (e.g., either one of the vacuum heads 800, 900 of FIG. 8 or 9) of the pick-and-place assembly 250 and the nozzle head 1015 of the fluid dispensing assembly 1000 are approximately the same size and/or cover approximately the same area (e.g., corresponding to a unit cell of the semiconductor wafer 600).

FIG. 12 shows the first example bonding machine 1100 in a second position 1200. The second position 1200 shows the pick-and-place assembly 250 having picked up a second batch of dies 1220 and moved to position the second batch of dies 1220 to be above the water droplets 700 dispensed by the fluid dispensing assembly 1000 just after the bonding machine 1100 was in the first position 1120 represented in FIG. 11. Inasmuch as the pick-and-place assembly 250 and the fluid dispensing assembly 1000 are affixed to move as a unit, by positioning the second batch of dies 1220 above the water droplets 700, the fluid dispensing assembly 1000 is shifted to be above a next adjacent area of the semiconductor wafer 600.

FIG. 13 shows the first example bonding machine 1100 in a third position 1300. The third position 1300 shows the pick-and-place assembly 250 placing the second batch of dies 1220 (e.g., a second instance of the dies 135, 210, 220, 230) on the wafer 600. Also, in the third position 1300, the fluid dispensing assembly 1000 may dispense water droplets 700 on the next set of hydrophilic regions 620 for placing subsequent batches of dies (e.g., subsequent instances of the dies 135, 210, 220, 230). Thus, as shown in FIG. 13, the pick-and-place assembly 250 and the fluid dispensing assembly 1000 are operating in parallel to place the dies on the water droplets 700 and to dispense additional water droplets 700 for subsequent batches of dies to be positioned.

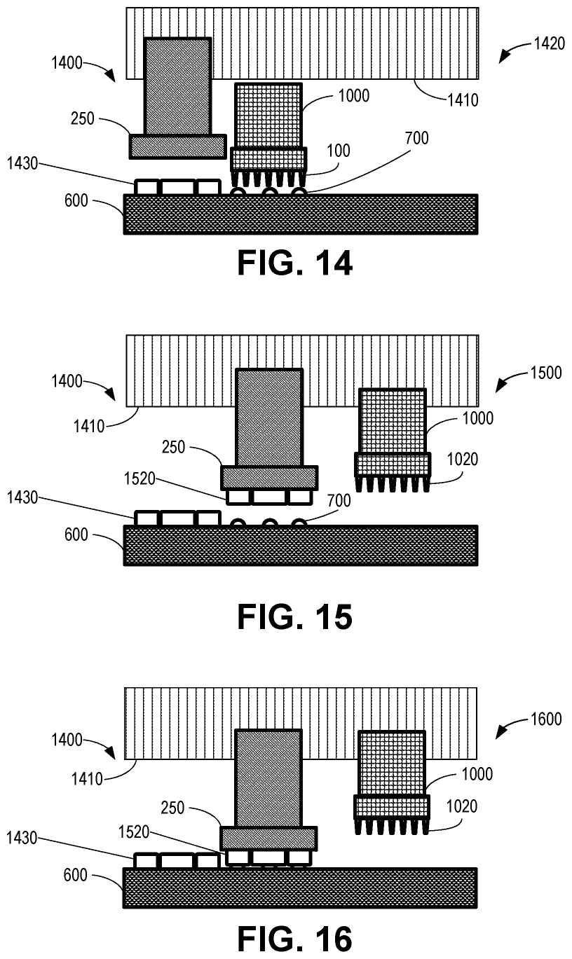

FIGS. 14-16 illustrate a second example bonding machine 1400 for dispensing fluid and picking and placing the dies of FIG. 3. The second example bonding machine 1400 includes the example fluid dispensing assembly 1000 of FIG. 10 and the example pick-and-place assembly 250 of FIG. 2. In this example, the fluid dispensing assembly 1000 and the pick-and-place assembly 250 as separate components capable of being moved relative to one another. The second example bonding machine 1400 also includes a second gantry 1410. In some examples, the second gantry 1410 includes more than one gantry for independently moving the pick-and-place assembly 250 and the fluid dispensing assembly 1000. Any other configuration for being able to move the pick-and-place assembly 250 and/or the fluid dispensing assembly 1000 may be interchangeably used herein. In the illustrated example of FIGS. 14-16, the fluid dispensing assembly 1000 and the pick-and-place assembly 250 move independently of one another and can operate in parallel or in series. In some examples, the fluid dispenser controller circuitry 1060 operates the second gantry 1410 in FIGS. 14-16 to control movement of the nozzle head 1015 in addition to controlling the valves 1040 associated with the nozzles 1020.

Since the fluid dispensing assembly 1000 and the pick-and-place assembly 250 of FIGS. 14-16 operate independently, the nozzle head 1015 does not need to be the same size as the vacuum head 410. Rather, a smaller array of nozzles 1020 can be employed (e.g., smaller than the unit cell). In some examples, the fluid dispensing assembly 1000 includes a single nozzle 1020 that moves between the hydrophilic regions 620 within each unit cell to dispense fluid.

FIG. 14 shows the second example bonding machine 1400 in a first position 1420. The first position 1420 of FIG. 14 shows the pick-and-place assembly 250 just after having placed a third batch of dies 1430 (e.g., the dies 135, 210, 220, 230) and the fluid dispensing assembly 1000 just after having dispensed the water droplets 700 on the wafer 600 adjacent to the third batch of dies 1430 in preparation for a fourth batch of dies. The picking up of the dies 135, 210, 220, 230 and the dispensing of the water droplets 700 need not be performed at the same time and can be performed by dispensing the water droplets 700 first and then picking up the dies 135, 210, 220, 230. In some examples, however, the picking up of the dies 135, 210, 220, 230 and dispensing of the water droplets 700 are performed at the same time. As disclosed herein, the pick-and-place assembly 250 can pick up any arrangement of dies, and thus the dies 135, 210, 220, 230 can be in any order or arrangement when picked up by the pick-and-place assembly 250.

FIG. 15 shows the second example bonding machine 1400 in a second position 1500. The second position 1500 of FIG. 15 shows the pick-and-place assembly 250 having picked up a fourth batch of dies 1520 and moved to position the fourth batch of dies 1520 to be above the water droplets 700 dispensed by the fluid dispensing assembly 1000 just after the bonding machine 1400 was in the first position 1420 represented in FIG. 14. Inasmuch as the pick-and-place assembly 250 and the fluid dispensing assembly operate independently, while the pick-and-place assembly 250 is positioning the fourth batch of dies 1520 over the water droplets 700 in the second position 1500 of FIG. 15, the fluid dispensing assembly 1000 can be dispensing water droplets 700 for subsequent batches of dies.

FIG. 16 shows the second example bonding machine 1400 in a third position 1600. The third position 1600 of FIG. 16 shows the pick-and-place assembly 250 placing the fourth batch of dies 1520 (e.g., a second instance of the dies 135, 210, 220, 230) on the wafer 600. In some examples, while the pick-and-place assembly 250 is placing the fourth batch of dies 1520 on the water droplets 700 in the third position 1600 of FIG. 16, the fluid dispensing assembly 1000 can be dispensing water droplets 700 for subsequent batches of dies (e.g., subsequent instances of the dies 135, 210, 220, 230).

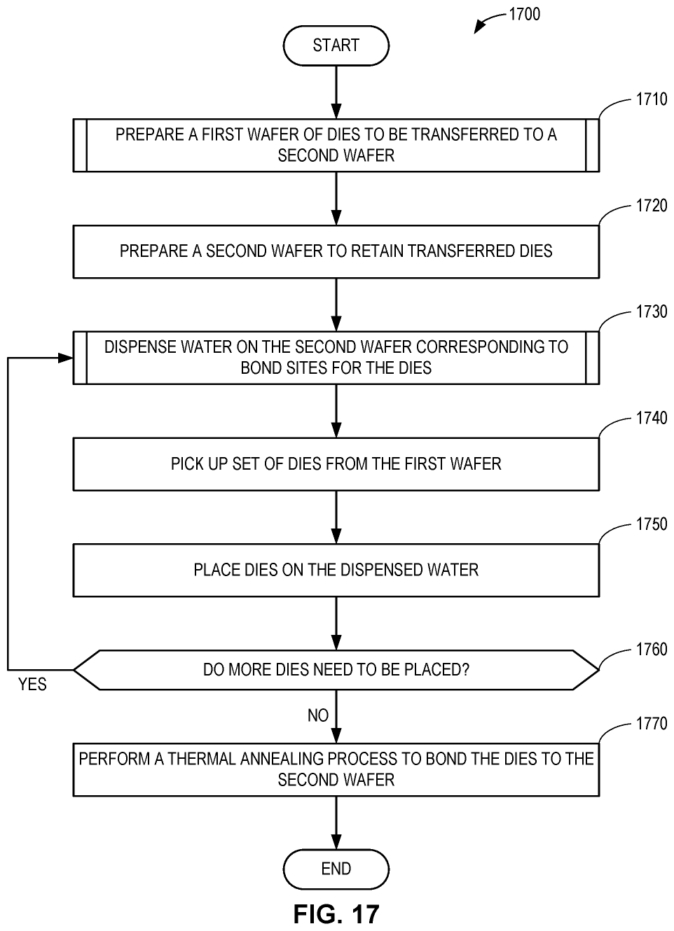

FIGS. 17-19 are flowcharts representative of example methods of operating the example bonding machines 1100, 1400 to implement the example die-to-wafer self-aligning and bonding process 100 of FIG. 1. While the flowcharts of FIGS. 17-19 represent example operations that can be used to implement the example die-to-wafer self-aligning and bonding process 100, the operations can be implemented by machine readable instructions which may be executed or instantiated by programmable circuitry.

FIG. 17 is a flowchart representative of example machine readable instructions and/or example operations 1700 that may be performed through a manufacturing process and/or executed, instantiated, and/or performed by programmable circuitry to perform the semiconductor die to wafer self-aligning and bonding process 100 of FIG. 1. The example machine-readable instructions and/or the example operations 1700 of FIG. 17 begin at block 1710, at which a first wafer (e.g., the top wafer 120 in FIG. 1) of dies (e.g., the dies 135, 210, 220, 230) is prepared to be transferred to a second wafer (e.g., the bottom wafer 130). In some examples, the dies 135, 210, 220, 230 come from cutting a single wafer. In other examples, the dies 135, 210, 220, 230 come from cutting/combining dies from multiple wafers into a reconstituted wafer (e.g., see FIG. 2).

Once the first wafer of dies is prepared, the second wafer is prepared to retain the transferred dies. (Block 1720). In some examples, preparing the second wafer includes subjecting the second wafer to a plasma activation process and a cleaning. In examples disclosed herein, the second wafer is subjected to a plasma activation process (e.g., the second plasma activation 150) to increase/improve adhesion properties on the second wafer 130 through surface chemistry modifications. Specifically, the plasma activation of the hydrophilic regions 620 ensure the bonding sites (e.g., where the dies 135, 210, 220, 230 are placed on the second wafer 130) have increased adhesion properties. In examples disclosed herein, the second wafer is subjected to a cleaning (e.g., the second cleaning 155) to ensure that no debris or foreign bodies/objects are left on the surface of the second wafer that could interfere with the bonding of the dies 135, 210, 220, 230 to the second wafer.

Once the second wafer has been prepared, the fluid dispenser controller circuitry 1060 dispenses water on the second wafer corresponding to bond sites for the dies 135, 210, 220, 230. (Block 1730). In examples disclosed herein, the water is dispensed on the second wafer by the fluid dispensing assembly 1000. In some examples, the fluid dispenser controller circuitry 1060 determines a proper amount of water to be dispensed based on the size and/or orientation of the dies 135, 210, 220, 230.

Once the water has been dispensed by the fluid dispensing assembly 1000 (as controlled by the fluid dispenser controller circuitry 1060) on the second wafer, the pick-and-place-assembly 250 picks up a set (e.g., batch) of the dies 135, 210, 220, 230. (Block 1740). In some examples, the set or batch of dies corresponds to all dies corresponding to a particular unit cell of the second wafer. In some examples, the dies 135, 210, 220, 230 picked up include dies cut from multiple different wafers (e.g., see FIG. 2).

Once the dies 135, 210, 220, 230 have been picked up, the pick-and-place-assembly 250 places the dies 135, 210, 220, 230 on the dispensed water. (Block 1750). In examples disclosed herein, the accuracy required of the pick-and-place-assembly 250 to place the dies 135, 210, 220, 230 on the water is relatively low (e.g., a lateral offset of more than 1 μm and up to as much as 100 μm or more is acceptable) due to the capillary forces acting on the dies 135, 210, 220, 230 once placed to self-align the dies 135, 210, 220, 230 on the hydrophilic regions of the second wafer.

Once the dies 135, 210, 220, 230 have been placed, a determination is made as to whether more dies need to be placed. (Block 1760). When it is determined that more dies need to be placed (e.g., block 1760 returns a result of YES), blocks 1730 through 1760 are repeated until all dies have been placed. As discussed above, in some examples, water is dispensed (at block 1730) for a next set or batch of dies in parallel with (e.g., simultaneously with) the placement of a previous set or batch of dies.

Once all dies have been placed and a determination is made that no additional dies are to be placed (e.g., block 1760 returns a result of NO), then a thermal annealing process (e.g., the thermal annealing process 170) is performed on the second wafer with all dies having been placed on the second wafer. (Block 1770). In the examples disclosed herein, the thermal annealing process forms covalent bonds at a dielectric-to-dielectric bonding interface of the dies 135, 210, 220, 230 to bond the dies 135, 210, 220, 230 to the second wafer 130 and also facilitates the diffusion of copper between interfacing metal surfaces for direct copper-to-copper bonding.

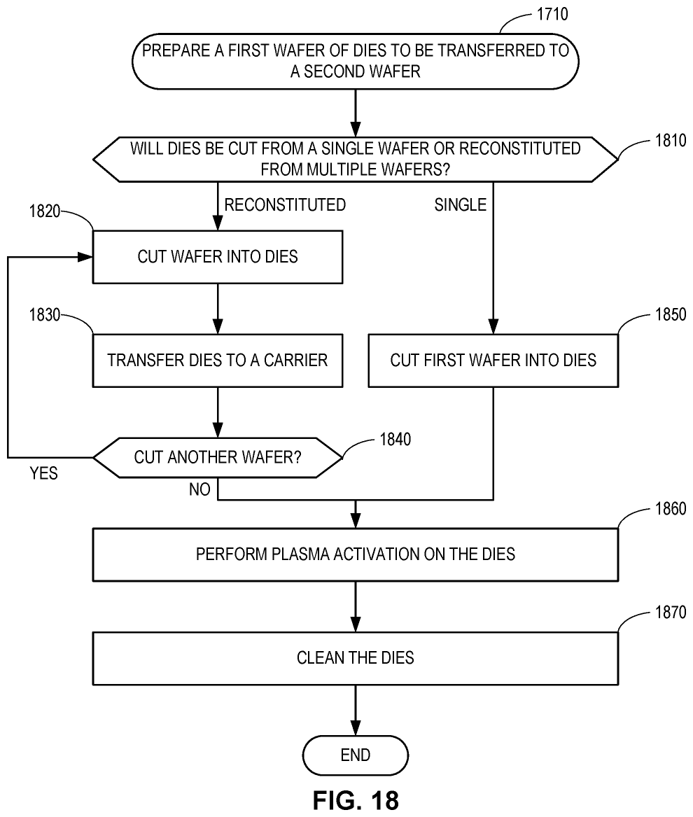

FIG. 18 is a flowchart representative of example machine readable instructions and/or example operations that may be performed through a manufacturing process and/or executed, instantiated, and/or performed by programmable circuitry to implement block 1710 of FIG. 17. The example machine-readable instructions and/or the example operations of FIG. 18 begin at block 1810, at which a determination is made as to whether the dies 135, 210, 220, 230 will be cut from a single wafer or reconstituted from multiple wafers.

When a determination is made that the dies 135, 210, 220, 230 will be reconstituted (e.g., block 1810 returns a result of RECONSTITUTED), a wafer (e.g., the first wafer) is cut into dies. (Block 1820). In some examples, the wafer to be cut can be cut into multiple different sizes and orientations of individual dies.

Once the wafer is cut, the cut dies are transferred to a carrier (e.g., the carrier 260 of FIG. 2). (Block 1830). In some examples, the carrier 260 creates a common area which allows the pick-and-place assembly 250 to pick up the cut dies from a concentrated area (e.g., instead of going to multiple areas to pick up the necessary dies).

Once the dies are transferred to the carrier 260, a determination is made whether additional wafers are to be cut into dies. (Block 1840). When a determination is made that additional wafers are to be cut (e.g., block 1840 returns a result of YES), block 1820 through 1840 are repeated until no additional wafers are to be cut. During each iteration, the new dies (from a new wafer) are transferred to the same carrier 260, thereby reconstituting the dies from multiple wafers onto a single wafer or substrate.

When a determination is made that the dies are to be cut from a single wafer (e.g., block 1810 returns a result of SINGLE), then the first wafer is cut into dies. (Block 1850). In some examples, the dies cut from the first wafer include individual dies of different shapes and orientations to be placed on the second wafer.

Once all wafers have been cut into dies (e.g., block 1840 returns a result of NO) or when the first wafer has been cut into dies (e.g., block 1850 completes), a plasma activation process (e.g., the first plasma activation 140) is performed on the dies 135, 210, 220, 230 to modify the bonding surfaces of the dies 135, 210, 220, 230. (Block 1860). In some examples, the plasma activation process is performed to activate the dies 135, 210, 220, 230 for better adhesive properties when placed on the second wafer.

Once the plasma activation process is performed on the dies 135, 210, 220, 230, the dies 135, 210, 220, 230 are subjected to a cleaning (e.g., the first cleaning 145). (Block 1725). In some examples, the first cleaning is to ensure that no debris or foreign bodies remain on the dies 135, 210, 220, 230 before they are bonded to the second wafer.

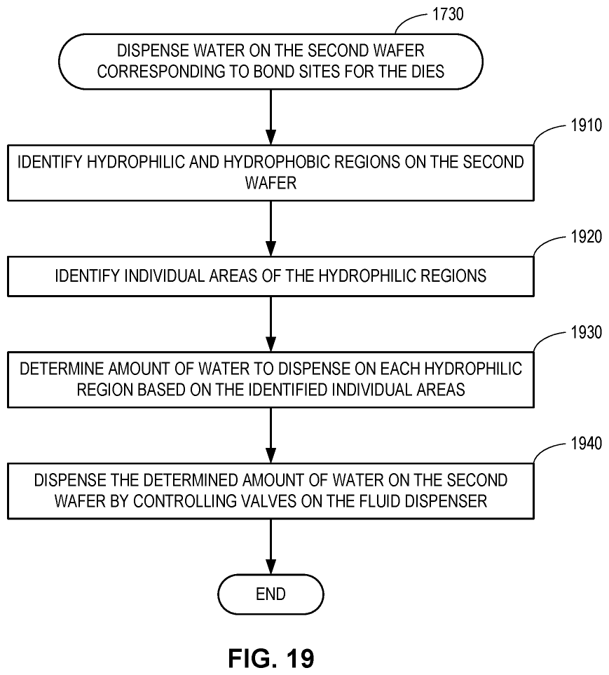

FIG. 19 is a flowchart representative of example machine readable instructions and/or example operations that may be performed through a manufacturing process and/or executed, instantiated, and/or performed by programmable circuitry to dispense water on the second wafer using the fluid dispensing assembly 1000. The example machine-readable instructions and/or the example operations of FIG. 19 begin at block 1910, at which the fluid dispenser controller circuitry 1060 identifies the hydrophilic and hydrophobic regions on the second wafer. In examples disclosed herein, the water is to be placed on the hydrophilic regions to allow the dies 135, 210, 220, 230 to self-align.

Once the fluid dispenser controller circuitry 1060 identifies the hydrophilic regions on the second wafer, the fluid dispenser controller circuitry 1060 identifies individual areas (e.g., length by width) of the hydrophilic regions identified. (Block 1920). In some examples, the identifying of the individual areas is used to determine which nozzles 1020 are to be used to dispense the fluid/water. For example, if a nozzle 1020 is located over a region of the second wafer in which there is no hydrophilic area, then that nozzle 1020 will not be used to dispense the fluid/water.

Once the fluid dispenser controller circuitry 1060 identifies the individual areas of the hydrophilic regions, the fluid dispenser controller circuitry 1060 determines an amount of water to dispense on each hydrophilic area based on the individual areas. (Block 1930). In some examples, larger areas can take larger amounts of water to ensure that the dies 135, 210, 220, 230 will be properly aligned and bonded.

Once the fluid dispenser controller circuitry 1060 determines the amount of water to dispense on the hydrophilic areas, the fluid dispenser controller circuitry 1060 regulates the dispensing of the determined amount of water on the second wafer by controlling the valves 1040 on the fluid dispensing assembly 1000. (Block 1940). In some examples, where larger portions of water are desired, the valve 1040 for that particular nozzle 1020 is opened more than a valve 1040 that is to dispense a smaller portion of water. Additionally or alternatively, in some examples, more valves 1040 associated with nozzles 1020 aligned for the larger area are opened than for the nozzles aligned with a smaller area. In some examples, when the nozzle head is smaller than an overall area containing the hydrophilic regions to which water is to be dispensed (e.g., smaller than a full unit cell), the fluid dispenser controller circuitry 1060 can cause the nozzle head to move to different locations to facilitate the dispensing of the water. As such, each valve 1040 is controlled independently to regulate the portion of water to be dispensed based on the size, orientation, and/or arrangement of the hydrophilic regions that are to receive respective ones of the dies 135, 210, 220, 230 transferred from the first wafer.

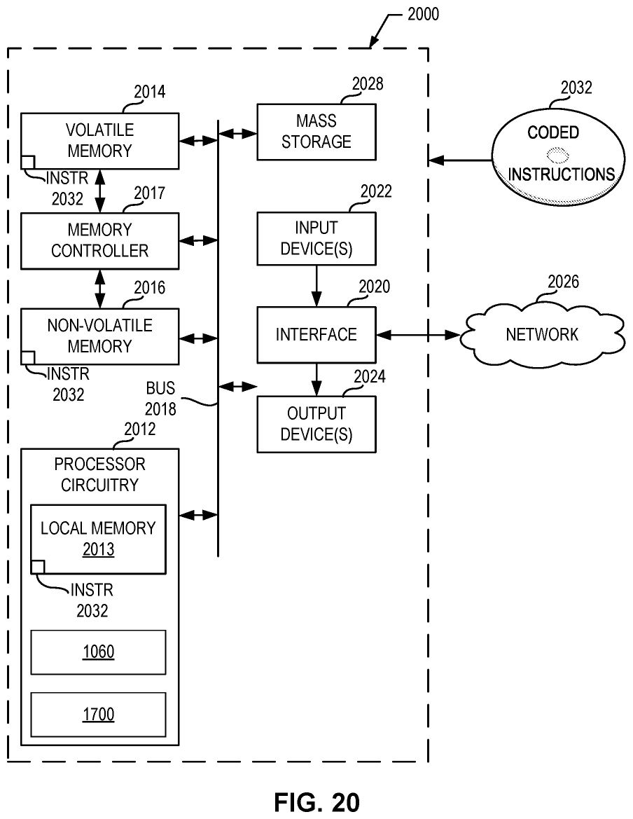

FIG. 20 is a block diagram of an example programmable circuitry platform 2000 structured to execute and/or instantiate the example machine-readable instructions and/or the example operations of FIGS. 17-19 to implement the example semiconductor die to wafer self-aligning and bonding process 100 of FIG. 1. The programmable circuitry platform 2000 can be, for example, a server, a personal computer, a workstation, a self-learning machine (e.g., a neural network), a mobile device (e.g., a cell phone, a smart phone, a tablet such as an iPad™), or any other type of computing and/or electronic device.

The programmable circuitry platform 2000 of the illustrated example includes programmable circuitry 2012. The programmable circuitry 2012 of the illustrated example is hardware. For example, the programmable circuitry 2012 can be implemented by one or more integrated circuits, logic circuits, FPGAs, microprocessors, CPUs, GPUs, DSPs, and/or microcontrollers from any desired family or manufacturer. The programmable circuitry 2012 may be implemented by one or more semiconductor based (e.g., silicon based) devices. In this example, the programmable circuitry 2012 implements the example semiconductor die to wafer self-aligning and bonding process 100 of FIG. 1 and fluid dispenser controller circuitry 1060.

The programmable circuitry 2012 of the illustrated example includes a local memory 2013 (e.g., a cache, registers, etc.). The programmable circuitry 2012 of the illustrated example is in communication with main memory 2014, 2016, which includes a volatile memory 2014 and a non-volatile memory 2016, by a bus 2018. The volatile memory 2014 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 2016 may be implemented by flash memory and/or any other desired type of memory device. Access to the main memory 2014, 2016 of the illustrated example is controlled by a memory controller 2017. In some examples, the memory controller 2017 may be implemented by one or more integrated circuits, logic circuits, microcontrollers from any desired family or manufacturer, or any other type of circuitry to manage the flow of data going to and from the main memory 2014, 2016.

The programmable circuitry platform 2000 of the illustrated example also includes interface circuitry 2020. The interface circuitry 2020 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 2022 are connected to the interface circuitry 2020. The input device(s) 2022 permit(s) a user (e.g., a human user, a machine user, etc.) to enter data and/or commands into the programmable circuitry 2012. The input device(s) 2022 can be implemented by, for example, a keyboard, a button, a mouse, a touchscreen, a trackpad, a trackball, an isopoint device, and/or a voice recognition system.

One or more output devices 2024 are also connected to the interface circuitry 2020 of the illustrated example. The output device(s) 2024 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.). The interface circuitry 2020 of the illustrated example, thus, typically includes a graphics driver card, a graphics driver chip, and/or graphics processor circuitry such as a GPU.

The interface circuitry 2020 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 2026. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 2000 of the illustrated example also includes one or more mass storage discs or devices 2028 to store firmware, software, and/or data. Examples of such mass storage discs or devices 2028 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 2032, which may be implemented by the machine readable instructions of FIGS. 17-19, may be stored in the mass storage device 2028, in the volatile memory 2014, in the non-volatile memory 2016, and/or on at least one non-transitory computer readable storage medium such as a CD or DVD which may be removable.

From the foregoing, it will be appreciated that example systems, apparatus, articles of manufacture, and methods have been disclosed that implement methods and apparatus to self-align batch pick and place die bonding.

Example methods, apparatus, systems, and articles of manufacture to self-align batch pick and place die bonding are disclosed herein. Further examples and combinations thereof include the following:
Example 1 includes an apparatus comprising a fluid dispensing assembly to dispense first amounts of water onto first hydrophilic regions of a first semiconductor wafer at a first point in time, the first hydrophilic regions having a first arrangement, and dispense second amounts of water onto second hydrophilic regions of a second semiconductor wafer at a second point in time different than the first point in time, the second hydrophilic regions having a second arrangement different than the first arrangement, and a pick-and-place assembly to simultaneously position, at the first point in time, a first batch of dies onto the first amounts of water dispensed on the first semiconductor wafer, the first batch of dies corresponding to the first arrangement of the first hydrophilic regions, and simultaneously position, at the second point in time, a second batch of dies onto the second amounts of water dispensed on the second semiconductor wafer, the second batch of dies corresponding to the second arrangement of the second hydrophilic regions.
Example 2 includes the apparatus of example 1, wherein the first hydrophilic regions are surrounded by first hydrophobic regions, the first batch of dies to self-align when placed on the first semiconductor wafer using the first hydrophilic regions and the first hydrophobic regions on the first semiconductor wafer.
Example 3 includes the apparatus of example 1, wherein the first amounts of water are sufficient to spread across the first hydrophilic regions when the first batch of dies are positioned thereon, the first amounts of water to be retained by first hydrophobic regions surrounding the first hydrophilic regions.
Example 4 includes the apparatus of example 1, wherein the pick-and-place assembly includes a vacuum head, the vacuum head including one or more openings, a vacuum force to be applied through the one or more openings on the vacuum head to pick up the first batch of dies at the first point in time and to pick up the second batch of dies at the second point in time.
Example 5 includes the apparatus of example 4, wherein the one or more openings include a plurality of holes distributed across the vacuum head.
Example 6 includes the apparatus of example 4, wherein the one or more openings are dimensioned and spaced apart to pick up different arrangements of dies including the first arrangement and the second arrangement.
Example 7 includes the apparatus of example 4, wherein the one or more openings include first elongate apertures extending in a first direction, and second elongate apertures traversing the first elongate apertures.
Example 8 includes the apparatus of example 1, wherein the fluid dispensing assembly includes a nozzle head, and a plurality of dispensing nozzles distributed across the nozzle head of the fluid dispensing assembly to dispense the first amounts of water and the second amounts of water on the first and second semiconductor wafers.
Example 9 includes the apparatus of example 8, wherein the fluid dispensing assembly includes a plurality of valves operably coupled to the plurality of dispensing nozzles to dispense the first amounts of water and the second amounts of water from a water source, and controller circuitry to control the plurality of valves, the plurality of valves to regulate flow of the first amounts of water and the second amounts of water through the plurality of dispensing nozzles.
Example 10 includes the apparatus of example 1, wherein the fluid dispensing assembly and the pick-and-place assembly are fixedly coupled to one another, the fluid dispensing assembly and the pick-and-place assembly to respectively dispense water and position dies in parallel.
Example 11 includes the apparatus of example 1, wherein the fluid dispensing assembly and the pick-and-place assembly move independently, the fluid dispensing assembly and the pick-and-place assembly to respectively dispense water and position dies independently.
Example 12 includes a method comprising dispensing first amounts of water on respective ones of first hydrophilic regions of a first semiconductor wafer at a first point in time, the first hydrophilic regions having a first arrangement, and simultaneously positioning, at the first point in time, a first set of dies on the first amounts of water on the first semiconductor wafer, the first set of dies dimensioned and spaced apart according to the first arrangement of the first hydrophilic regions, dispensing second amounts of water on respective ones of second hydrophilic regions of a second semiconductor wafer at a second point in time, the second hydrophilic regions having a second arrangement different than the first arrangement, and simultaneously positioning, at the second point in time, a second set of dies on the second amounts of water on the second semiconductor wafer, the second set of dies dimensioned and spaced apart according to the second arrangement of the second hydrophilic regions.
Example 13 includes the method of example 12, further including self-aligning the first plurality of dies on the first semiconductor wafer using the first hydrophilic regions covered by the first amounts of water, the first hydrophilic regions surrounded by first hydrophobic regions on the first semiconductor wafer.
Example 14 includes the method of example 12, wherein the first amounts of water are sufficient to spread across the respective ones of the first hydrophilic regions when the first set of dies are positioned thereon, the first amounts of water to be retained by first hydrophobic regions surrounding the respective ones of the first hydrophilic regions.
Example 15 includes the method of example 12, further including performing a thermal annealing process to bond the first plurality of dies to the first semiconductor wafer.
Example 16 includes the method of example 12, further including cutting a third semiconductor wafer into a first plurality of dies, and cutting a fourth semiconductor wafer into a second plurality of dies, the first set of dies including a first die from the first plurality of dies and a second die from the second plurality of dies.
Example 17 includes the method of example 12, wherein the dispensing of the first amounts of water includes identifying a first area for a first one of the first hydrophilic regions, identifying a second area for a second one of the first hydrophilic regions, determining a first one of the first amounts of water based on the first area, determining a second one of the first amounts of water based on the second area, controlling a first valve to dispense the first one of the first amounts of water via a first nozzle, and controlling a second valve to dispense the second one of the first amounts of water via a second nozzle.
Example 18 includes an apparatus comprising means for dispensing water to dispense water onto first hydrophilic regions of a first semiconductor wafer at a first point in time, the first hydrophilic regions distributed across a first area, and dispense water onto second hydrophilic regions of a second semiconductor wafer at a second point in time different than the first point in time, the second hydrophilic regions distributed across a second area, the first and second areas having a same size and a same shape, at least one of a size, a shape, an orientation, or a placement of ones of the first hydrophilic regions within the first area to be different than at least one of a size, a shape, an orientation, or a placement of ones of the second hydrophilic regions within the second area, and means for positioning to position a first plurality of dies on the first hydrophilic regions, the water on the first hydrophilic regions to facilitate alignment of the first plurality of dies to the first hydrophilic regions, and position a second plurality of dies on the second hydrophilic regions, the water on the second hydrophilic regions to facilitate alignment of the second plurality of dies to the second hydrophilic regions.
Example 19 includes the apparatus of example 18, wherein the means for positioning and the means for dispensing operate in parallel.
Example 20 includes the apparatus of example 18, wherein the means for positioning and the means for dispensing operate in series.
Example 21 includes the apparatus of example 18, wherein the means for dispensing dispense a first amount of water onto a first region of the first hydrophilic regions and a second amount of water onto a second region of the first hydrophilic regions, the first amount of water different than the second amount of water.
Example 22 includes the apparatus of example 21, further including means for regulating the first amount of water and the second amount of water to be dispensed by the means for dispensing.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a fluid dispensing assembly to:
dispense first amounts of water onto first hydrophilic regions of a first semiconductor wafer at a first point in time, the first hydrophilic regions having a first arrangement; and
dispense second amounts of water onto second hydrophilic regions of a second semiconductor wafer at a second point in time different than the first point in time, the second hydrophilic regions having a second arrangement different than the first arrangement; and
a pick-and-place assembly to:
simultaneously position, at the first point in time, a first batch of dies onto the first amounts of water dispensed on the first semiconductor wafer, the first batch of dies corresponding to the first arrangement of the first hydrophilic regions; and
simultaneously position, at the second point in time, a second batch of dies onto the second amounts of water dispensed on the second semiconductor wafer, the second batch of dies corresponding to the second arrangement of the second hydrophilic regions.

2. The apparatus of claim 1, wherein the first hydrophilic regions are surrounded by first hydrophobic regions, the first batch of dies to self-align when placed on the first semiconductor wafer using the first hydrophilic regions and the first hydrophobic regions on the first semiconductor wafer.

3. The apparatus of claim 1, wherein the first amounts of water are sufficient to spread across the first hydrophilic regions when the first batch of dies are positioned thereon, the first amounts of water to be retained by first hydrophobic regions surrounding the first hydrophilic regions.

4. The apparatus of claim 1, wherein the pick-and-place assembly includes a vacuum head, the vacuum head including one or more openings, a vacuum force to be applied through the one or more openings on the vacuum head to pick up the first batch of dies at the first point in time and to pick up the second batch of dies at the second point in time.

5. The apparatus of claim 4, wherein the one or more openings include a plurality of holes distributed across the vacuum head.

6. The apparatus of claim 4, wherein the one or more openings are dimensioned and spaced apart to pick up different arrangements of dies including the first arrangement and the second arrangement.

7. The apparatus of claim 4, wherein the one or more openings include:
first elongate apertures extending in a first direction; and
second elongate apertures traversing the first elongate apertures.

8. The apparatus of claim 1, wherein the fluid dispensing assembly includes:
a nozzle head; and
a plurality of dispensing nozzles distributed across the nozzle head of the fluid dispensing assembly to dispense the first amounts of water and the second amounts of water on the first and second semiconductor wafers.

9. The apparatus of claim 8, wherein the fluid dispensing assembly includes:
a plurality of valves operably coupled to the plurality of dispensing nozzles to dispense the first amounts of water and the second amounts of water from a water source; and
controller circuitry to control the plurality of valves, the plurality of valves to regulate flow of the first amounts of water and the second amounts of water through the plurality of dispensing nozzles.

10. The apparatus of claim 1, wherein the fluid dispensing assembly and the pick-and-place assembly are fixedly coupled to one another, the fluid dispensing assembly and the pick-and-place assembly to respectively dispense water and position dies in parallel.

11. The apparatus of claim 1, wherein the fluid dispensing assembly and the pick-and-place assembly move independently, the fluid dispensing assembly and the pick-and-place assembly to respectively dispense water and position dies independently.

12. A method comprising:
dispensing first amounts of water on respective ones of first hydrophilic regions of a first semiconductor wafer at a first point in time, the first hydrophilic regions having a first arrangement; and
simultaneously positioning, at the first point in time, a first set of dies on the first amounts of water on the first semiconductor wafer, the first set of dies dimensioned and spaced apart according to the first arrangement of the first hydrophilic regions;
dispensing second amounts of water on respective ones of second hydrophilic regions of a second semiconductor wafer at a second point in time, the second hydrophilic regions having a second arrangement different than the first arrangement; and
simultaneously positioning, at the second point in time, a second set of dies on the second amounts of water on the second semiconductor wafer, the second set of dies dimensioned and spaced apart according to the second arrangement of the second hydrophilic regions.

13. The method of claim 12, further including self-aligning the first plurality of dies on the first semiconductor wafer using the first hydrophilic regions covered by the first amounts of water, the first hydrophilic regions surrounded by first hydrophobic regions on the first semiconductor wafer.

14. The method of claim 12, wherein the first amounts of water are sufficient to spread across the respective ones of the first hydrophilic regions when the first set of dies are positioned thereon, the first amounts of water to be retained by first hydrophobic regions surrounding the respective ones of the first hydrophilic regions.

15. The method of claim 12, further including performing a thermal annealing process to bond the first plurality of dies to the first semiconductor wafer.

16. The method of claim 12, further including:
cutting a third semiconductor wafer into a first plurality of dies; and
cutting a fourth semiconductor wafer into a second plurality of dies, the first set of dies including a first die from the first plurality of dies and a second die from the second plurality of dies.

17. The method of claim 12, wherein the dispensing of the first amounts of water includes:
identifying a first area for a first one of the first hydrophilic regions;
identifying a second area for a second one of the first hydrophilic regions;
determining a first one of the first amounts of water based on the first area;
determining a second one of the first amounts of water based on the second area;
controlling a first valve to dispense the first one of the first amounts of water via a first nozzle; and
controlling a second valve to dispense the second one of the first amounts of water via a second nozzle.

18. An apparatus comprising:
means for dispensing water to:
dispense water onto first hydrophilic regions of a first semiconductor wafer at a first point in time, the first hydrophilic regions distributed across a first area; and
dispense water onto second hydrophilic regions of a second semiconductor wafer at a second point in time different than the first point in time, the second hydrophilic regions distributed across a second area, the first and second areas having a same size and a same shape, at least one of a size, a shape, an orientation, or a placement of ones of the first hydrophilic regions within the first area to be different than at least one of a size, a shape, an orientation, or a placement of ones of the second hydrophilic regions within the second area; and
means for positioning to:
position a first plurality of dies on the first hydrophilic regions, the water on the first hydrophilic regions to facilitate alignment of the first plurality of dies to the first hydrophilic regions; and
position a second plurality of dies on the second hydrophilic regions, the water on the second hydrophilic regions to facilitate alignment of the second plurality of dies to the second hydrophilic regions.

19. The apparatus of claim 18, wherein the means for dispensing dispense a first amount of water onto a first region of the first hydrophilic regions and a second amount of water onto a second region of the first hydrophilic regions, the first amount of water different than the second amount of water.

20. The apparatus of claim 19, further including means for regulating the first amount of water and the second amount of water to be dispensed by the means for dispensing.
